(19) United States
(12) Patent Application Publication
(10) Pub. No.: US 2002/0102821 A1
(43) Pub. Date: Aug. 1, 2002

(54) Mask pattern design to improve quality uniformity in lateral laser crystallized poly-Si films

(76) Inventor: Apostolos Voutsas, Vancouver, WA (US)

Correspondence Address: Matthew D. Rabdau, Patent Attorney, Sharp Laboratories of America, Inc., 5750 NW Pacific Rim Boulevard, Camas, WA, 98607, US

(21) Appl. No.: 09/774,270

(22) Filed: Jan. 29, 2001

(51) Int. Cl. H01L 21/00; H01L 21/84; H01L 21/20; C30B 1/00; H01L 21/36

(52) U.S. Cl. 438/487; 438/149; 438/150; 438/486

(57) ABSTRACT

A method is provided to improve uniformity between the channel characteristics of multiple sets of thin film transistors (TFTs) formed with different orientations on a polycrystalline film. The method is well suited to the production of TFTs for use as drivers on liquid crystal display devices, as well as other devices. TFT channels are formed over a polycrystalline region on a substrate such that the predominant crystal orientation of the polycrystalline region is a compromise orientation between an ideal orientation for one set of TFTs and an ideal orientation for another set of TFTs. In one preferred embodiment, where a set of row drivers and a set of column drivers are 90 degrees relative to each other, the predominant crystal orientation would be at approximately 45 degrees relative to both set of drivers.

### CROSS-REFERENCES

The subject matter of this application is related to the application entitled Method of Optimizing Channel Characteristics Using Multiple Masks To Form Laterally-Crystallized ELA Poly-Si Films by inventors Apostolos Voutsas, John W. Hartzell and Yukihiko Nakata filed on the same date as this application (Attorney Docket No. SLA 0511).

The subject matter of this application is related to the application entitled Method of Optimizing Channel Characteristics using Laterally-Crystallized ELA Poly-Si Films by inventors Apostolos Voutsas, John W. Hartzell and Yukihiko Nakata filed on the same date as this application (Attorney Docket No. SLA 0513).

All of these applications, which are not admitted to be prior art with respect to the present invention by their mention here, are incorporated herein by this reference.

### BACKGROUND OF THE INVENTION

This invention relates generally to semiconductor technology and more particularly to a method of forming polycrystalline silicon within an amorphous silicon film.

Polycrystalline silicon thin film transistors (TFTs) can be used in a variety of microelectronics applications, especially active matrix liquid crystal displays (LCDs).

Thin film transistors (TFTs) used in liquid crystal displays (LCDs) or flat panel displays of the active matrix display type are fabricated on silicon films deposited on a transparent substrate. The most widely used substrate is glass. Amorphous silicon is readily deposited on glass. Amorphous silicon limits the quality of TFTs that can be formed. If driver circuits and other components are to be formed on the display panel, as well as switches associated with each pixel, crystalline silicon is preferred.

Silicon is often referred to as either amorphous or crystalline, including single crystal silicon. The term crystalline silicon can refer to either single crystal silicon, polycrystalline silicon, or in some cases materials with significant quantities of micro-crystal structures. For many application, single crystal material is most desirable. But, single crystal silicon is not readily producible. Amorphous silicon can be crystallized to form crystalline silicon by solid-phase crystallization. Solid-phase crystallization is carried out by high temperature annealing. But, glass substrates cannot withstand the temperatures necessary to melt and crystallize silicon. Quartz substrates can withstand high temperature annealing, but quartz substrates are too expensive for most LCD applications.

Because glass deforms when exposed to temperatures above 600° C., low-temperature crystallization (preferably below 550° C.) is used for solid-phase processing of silicon on glass. The low-temperature process requires long anneal times (at least several hours). Such processing is inefficient and yields polycrystalline silicon TFTs that have relatively low field effect mobility and poor transfer characteristics. Polycrystalline silicon produced by solid-phase crystallization of as-deposited amorphous silicon on glass suffers due to small crystal size and a high density of intragrain defects in the crystalline structure.

Excimer laser annealing (ELA) has been actively investigated as an alternative to low-temperature solid-phase crystallization of amorphous silicon on glass. In excimer laser annealing, a high-energy pulsed laser directs laser radiation at selected regions of the target film, exposing the silicon to very high temperatures for short durations. Typically, each laser pulse covers only a small area (several millimeters in diameter) and the substrate or laser is stepped through an exposure pattern of overlapping exposures, as is known in the art.

Lateral crystallization by excimer laser annealing (LC-ELA) is one method that has been used to form high quality polycrystalline films having large and uniform grains. LC-ELA also provides controlled grain boundary location.

According to one method of conducting LC-ELA, an initially amorphous silicon film is irradiated by a very narrow laser beamlet, typically 3-5 micrometers wide. Passing a laser beam through a mask that has slits forms the beamlet, which is projected onto the surface of the silicon film.

The beamlet crystallizes the amorphous silicon in its vicinity forming one or more crystals. The crystals grow within the area irradiated by the beamlet. The crystals grow primarily inward from edges of the irradiated area toward the center. The distance the crystal grows, which is also referred to as the lateral growth length, is a function of the amorphous silicon film thickness and the substrate temperature. Typical lateral growth lengths for 50 nm films is approximately 1.2 micrometers. After an initial beamlet has crystallized a portion of the amorphous silicon, a second beamlet is directed at the silicon film at a location less than half the lateral growth length from the previous beamlet. Moving either the laser, along with its associated optics, or by moving the silicon substrate, typically using a stepper, changes the location of the beamlet. Stepping a small amount at a time and irradiating the silicon film causes crystal grains to grow laterally from the crystal seeds of the poly-Si material formed in the previous step. This achieves lateral pulling of the crystals in a manner similar to zone-melting-crystallization (ZMR) methods or other similar processes.

As a result of this lateral growth, the crystals produced tend to attain high quality along the direction of the advancing beamlets, also referred to as the “pulling direction.” However, the elongated crystal grains produced are separated by grain boundaries that run approximately parallel to the long grain axes, which are generally perpendicular to the length of the narrow beamlet.

When this poly-Si material is used to fabricate electronic devices, the total resistance to carrier transport is affected by the combination of barriers that a carrier has to cross as it travels under the influence of a given potential. Due to the additional number of grain boundaries that are crossed when the carrier travels in a direction perpendicular to the long grain axes of the poly-Si material, the carrier will experience higher resistance as compared to the carrier traveling parallel to the long grain axes. Therefore, the performance of TFTs fabricated on poly-Si films formed using LC-ELA will depend upon the orientation of the TFT channel relative to the long grain axes, which corresponds to the main growth direction. Typically, TFT performance varies by a factor of between 2 and 4 as a function of orientation relative to the main growth direction.

This difference in performance is undesirable from the point of view that as LCD resolution increases, or as panel size decreases, size limitations make it more desirable to have column drivers and row drivers oriented at ninety degrees relative to each other. Potentially resulting in one set of drivers having significantly different characteristics relative to the other.

### SUMMARY OF THE INVENTION

Accordingly, a method of forming thin film transistors (TFTs) on a substrate is provided. A substrate is selected. The substrate selected will depend upon the desired application. For display devices the substrate is preferably transparent. Available transparent substrates include quartz, glass and plastic. An amorphous silicon film is deposited over the substrate. A laser beam is directed through a mask to irradiate the substrate over a region on the substrate. The region is annealed using a lateral crystallization process. In a preferred embodiment of the present invention, the mask has at least one slit positioned at an angle. The angle is nonperpendicular, and preferably between 30 and 60 degrees relative to a subsequent TFT channel's orientation. As the mask is moved and the laser beam is directed through the mask onto the substrate, crystals produced during preceding exposures will act as seed crystals for subsequent exposures. The crystals will grow predominantly in a direction perpendicular to the length of the slit, even if the direction of the mask movement is not perpendicular to the direction of the slit.

Another embodiment of the present invention is a display device having row drivers and column drivers on a display substrate. The row drivers, and the column drivers are at some angle relative to each other, preferably approximately 90 degrees. The row drivers and the column drivers are formed over a polycrystalline region having a single predominant crystal orientation. To provide improved uniformity between the electrical properties of the row drivers and the column drivers, a predominant crystal orientation is produced that is not optimal for either set of drivers. In a preferred embodiment, the predominant crystal orientation is approximately 45 degrees relative to both row drivers and the column drivers.

### BRIEF DESCRIPTION OF THE DRAWINGS

FIG. 1 is a schematic cross-sectional view showing an ELA apparatus used in connection with the present method.

FIG. 2 shows a mask pattern.

FIG. 3 illustrates a step in the process of lateral crystallization using ELA.

FIG. 4 illustrates a step in the process of lateral crystallization using ELA.

FIG. 5 illustrates a step in the process of lateral crystallization using ELA.

FIG. 6 illustrates the formation of a substrate with a crystal orientation.

FIG. 7 illustrates the formation of TFTs with channels aligned at an angle relative to the crystal orientation to optimize uniformity.

### DETAILED DESCRIPTION OF THE INVENTION

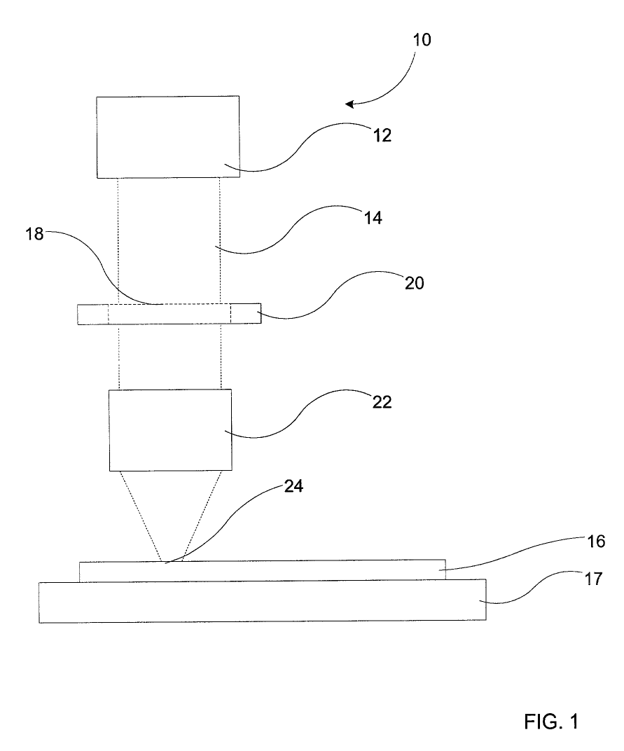

Referring to FIG. 1 a lateral crystallization excimer laser annealing (LC-ELA) apparatus 10 is shown. LC-ELA apparatus 10 has a laser source 12. Laser source 12 may include a laser (not shown) along with optics, including mirrors and lens, which shape a laser beam 14 (shown by dotted lines) and direct it toward a substrate 16, which is supported by a stage 17. The laser beam 14 passes through a mask 18 supported by a mask holder 20. The laser beam 14 preferably has output energy in the range of 0.8 to 1 Joule when the mask 18 is 50 mm×50 mm. Currently available commercial lasers such as Lambda Steel 1000 can achieve this output. As the power of available lasers increases, the energy of the laser beam 14 will be able to be higher, and the mask size will be able to increase as well. After passing through the mask 18, the laser beam 14 passes through demagnification optics 22 (shown schematically). The demagnification optics 22 reduce the size of the laser beam reducing the size of any image produced after passing through the mask 18, and simultaneously increasing the intensity of the optical energy striking the substrate 16 at a desired location 24. The demagnification is typically on the order of between 3× and 7× reduction, preferably a 5× reduction, in image size. For a 5× reduction the image of the mask 18 striking the surface at the location 24 has 25 times less total area than the mask, correspondingly increasing the energy density of the laser beam 14 at the location 24.

The stage 17 is preferably a precision x-y stage that can accurately position the substrate 16 under the beam 14. The stage 17 is preferably capable of motion along the z-axis, enabling it to move up and down to assist in focusing or defocusing the image of the mask 18 produced by the laser beam 14 at the location 24. The mask holder 20 is also capable of x-y movement.

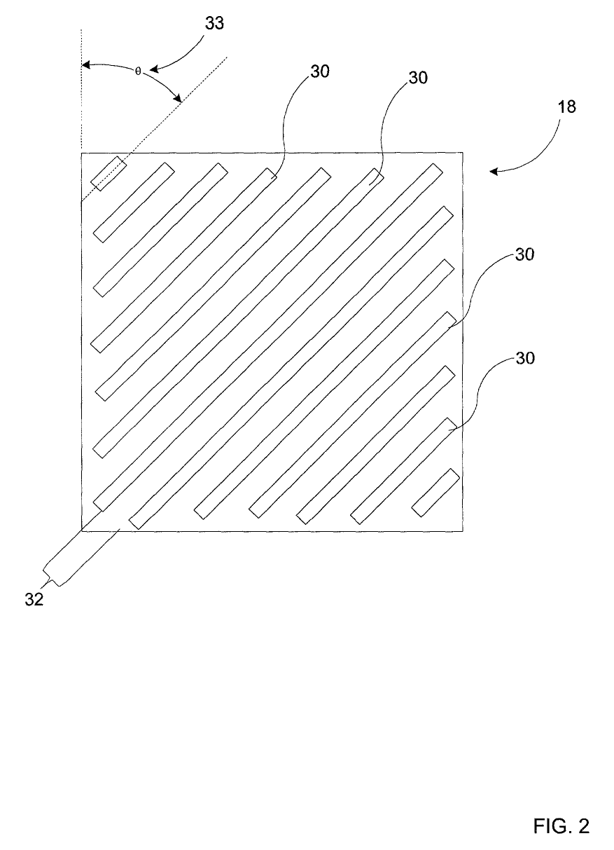

FIG. 2 shows the mask 18 having a plurality of slits 30 with a slit spacing 32. The mask 18 is shown as a square, but it is also possible for the mask to be rectangular. The slits are shown at an angle θ (identified by 33) relative to the edge of the mask. This angle is in the range between approximately 30 and 60 degrees, and in one preferred embodiment the angle is 45 degrees.

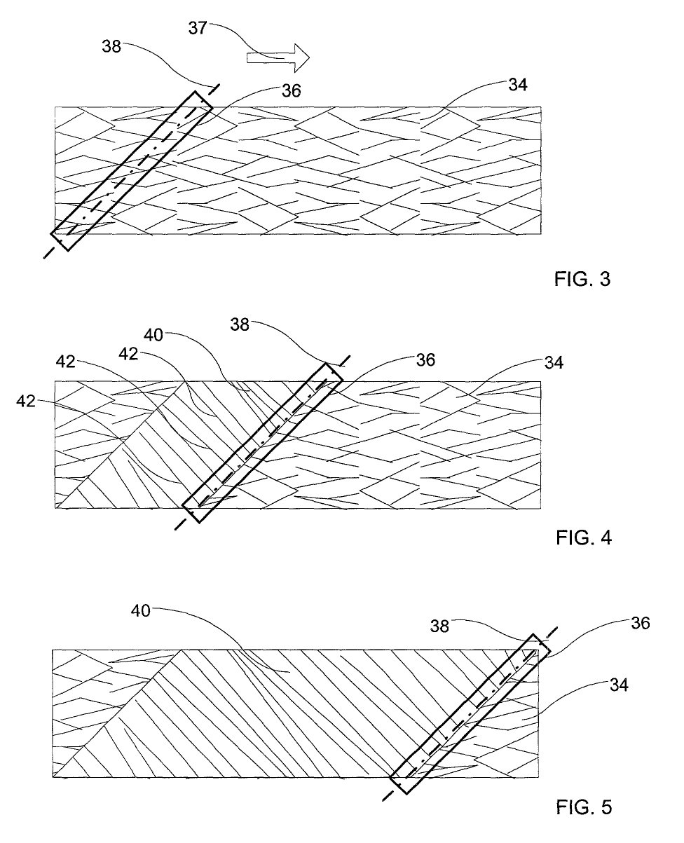

FIGS. 3 through 5 show the sequence of lateral crystallization employed as a portion of the present method. A region 34 of amorphous or polycrystalline silicon overlies the substrate. The rectangular area 36 corresponds to an image of one of the slits 30 projected onto the substrate. The dashed line 38 corresponds to the centerline of the image of the opening on the substrate.

FIG. 3 shows the region 34 just prior to crystallization. A laser pulse is directed at the rectangular area 36 causing the amorphous silicon to crystallize. After each pulse the image of the opening is advanced by an amount not greater than half the lateral crystal growth distance. A subsequent pulse is then directed at the new area. By advancing the image of the slits 30 a small distance, the crystals produced by preceding steps act as seed crystals for subsequent crystallization of adjacent material. It should be noted that in the present method, the slit is moved in a direction shown by an arrow 37, which is not perpendicular to the dashed line 38, also referred to as the centerline. In an embodiment the direction of movement is between 30 and 60 degrees, preferably 45 degrees, relative to the centerline. The crystal growth is primarily in the direction perpendicular to the centerline of the slits 30.

By repeating the process of advancing the image of the slits and firing short pulses the crystal is effectively pulled in the direction perpendicular to the slits orientation as the slit is moved to adjacent regions. In other methods, the movement is perpendicular to the centerline of the slit so that the crystal is pulled in the direction of movement. Here where the angle is different a more precise explanation is preferable. Since the laser is pulsed, the effective crystal growth is perpendicular to the centerline of the slit. As shown, with a 45 degree angle slit, the resulting predominant crystal orientation will be at a 45 degree angle as well.

FIG. 4 shows the region 34 after several pulses. As is clearly shown, the area 40 that has already been treated has formed elongated crystals that have grown in a direction substantially perpendicular to the length of the slit. Substantially perpendicular means that a majority of lines formed by crystal boundaries 42 could be extended to intersect with dashed line 38. As is shown the majority of the crystal boundaries are at a 45 degree angle, when using a 45 degree slit. Accordingly for a 30 degree slit angle, the crystal boundaries will be at 60 degrees, and for a 60 degree slit angle, the crystal boundaries will be at 30 degrees.

FIG. 5 shows the region 34 after several additional pulses following FIG. 4. The slits will preferably continue to advance a distance substantially equal to a distance on the substrate corresponding to the slit spacing 32. Each slit will preferably advance until it reaches the edge of a polycrystalline region formed by the slit immediately preceding it.

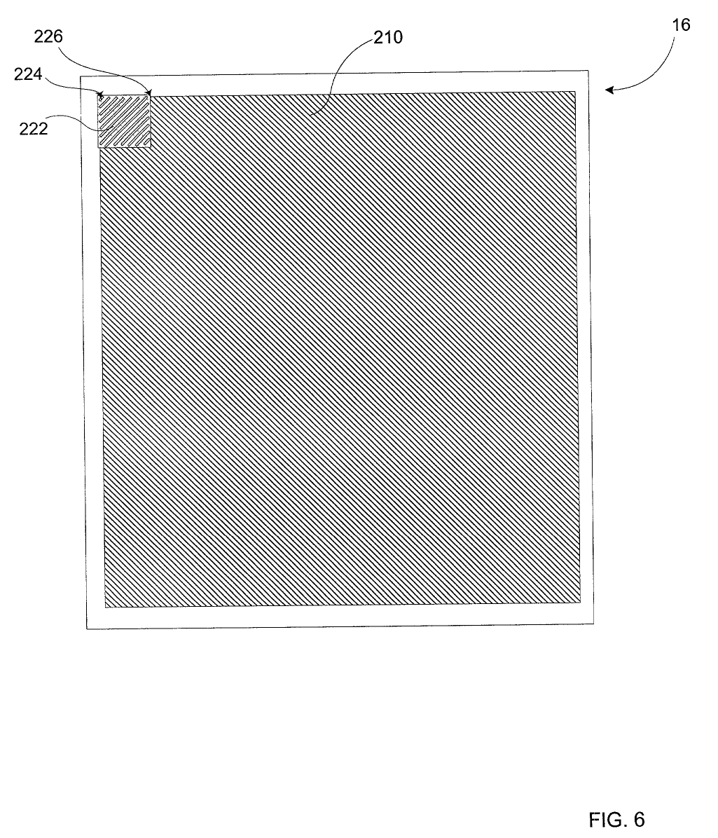

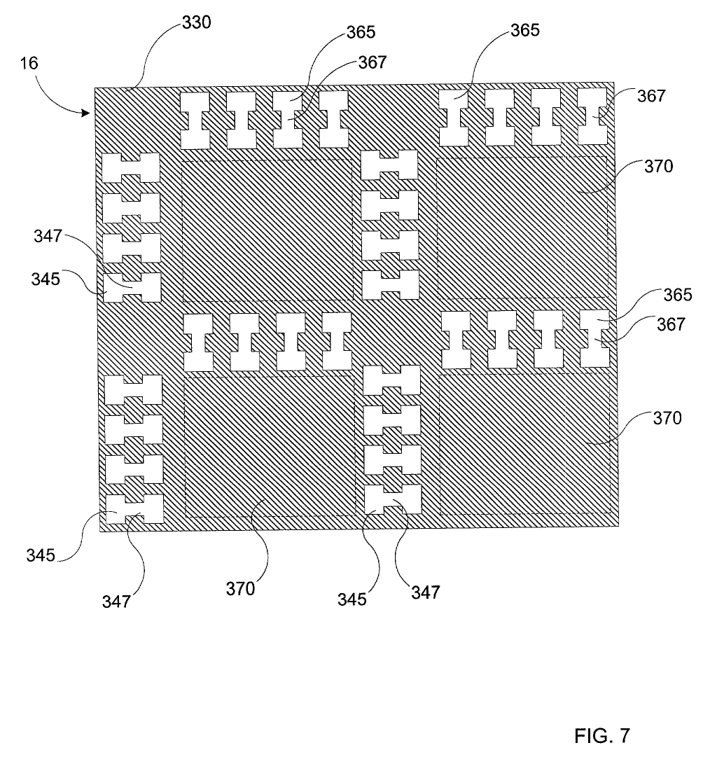

FIG. 6 shows the substrate 16 with a region 210. The image 222 of the mask is projected at a starting position 224.

In an embodiment of the present method, the image 222 is moved one step at a time by moving the mask stage. At each step a laser pulse crystallizes a portion of the silicon material. Once the image 222 has moved a distance corresponding to the slit spacing, the substrate is moved to position the image 222 over an adjacent position 226. The mask is then moved to crystallize the underlying region. By repeating this process across the substrate, a line of polycrystalline material having a predominant crystal orientation is formed. The image 222 is repositioned at a position corresponding the start of the adjacent un-crystallized region. The process is repeated until a region 210 is formed having the predominant crystal orientation. As shown this orientation is at a 45 degree angle relative to the edge of the region.

Once the substrate 16 has been processed to form at least one region with the desired crystal orientation, device elements are formed on the substrate as illustrated in FIG. 7. FIG. 7 is for illustration purposes, and as with the other drawings, is not drawn to scale. The substrate 16 has a polycrystalline region 330. A first set of TFTs 345 have been formed within polycrystalline region 330. First set of TFTs 345 have channels 347 oriented at a nonperpendicular, and non-parallel angle relative to the crystal orientation of the underlying region 330. As shown in the figure, the crystal orientation of region 330 is at a 45 degree angle relative to the channels 347, which are shown as horizontal. A second set of TFTs 365 having channels 367 are preferably substantially perpendicular to the first set of TFTs 345 and channels 347. The channels 367 are at an angle relative the crystal orientation of 45 degrees. Although illustrated using 45 degree angles, it would be possible to use other relative angles, including the range between 30 and 60 degrees.

Since FIG. 7 illustrates a display device, pixel regions 370 are shown along with row drivers and column drivers. The first set of TFTs 345 are also referred to as row drivers, and the second set of TFTs 365 are also referred to as the column drivers. For some applications, it may not be necessary to crystallize the entire substrate. Some regions may not need to be crystallized including, but not limited to the pixel regions.

Instead of having a polycrystalline orientation that is optimized for a one set of TFTs, the present method utilizes a polycrystalline orientation that is a compromise between the most desirable orientation for one set of TFTs or another. While, this does not produce optimal electrical properties for a given set of TFTs, it provides greater uniformity between electrical properties of sets of TFTs. Preferrably, when a 45 degree crystal orientation relative to channel orientation is used for perpendicular sets of TFTs the electrical properties should be substantially the same. If a different balance between electrical properties is desired, the relative performance can be modified by changing the relative crystal orientation to favor one set of TFTs over another.

Although the present method is well suited to producing display devices, it is also suited to other types of device produced using a polycrystalline material produced on an underlying substrate. In addition to row and column drivers, other circuitry unrelated to displays can be produced.

Several embodiments of the method of the present invention have been described. Variations on these embodiments will be readily ascertainable by one of ordinary skill in the art. Therefore, the description here is for illustration purposes only and should not be used to narrow the scope of the invention, which is defined by the claims as interpreted by the rules of patent claim construction.

What is claimed is:

1. A method of forming thin film transistors (TFTs) on a substrate comprising the steps of:
a) selecting a substrate;
b) depositing an amorphous silicon film over the substrate;
c) directing a laser pulse through a mask having a slit orientation onto a first region of the amorphous silicon film, whereby the first region is crystallized to form a first crystal region;
d) moving the mask in a nonperpendicular direction relative to the slit orientation to position the mask over a second region overlapping the first crystal region; and
e) directing a laser pulse through the mask onto the second region, whereby the first crystal region acts as a seed crystal during the crystallization of a second crystal region.

2. The method of claim 1, wherein the slit or orientation is between 30 degrees and 60 degrees.

3. The method of claim 1, wherein the slit orientation is substantially 45 degrees.

4. The method of claim 3, wherein the nonperpendicular direction of movement is 45 degrees relative to the slit orientation.

5. A method of processing a substrate comprising the steps of:
a) depositing amorphous silicon on a substrate;
b) annealing a region on the substrate using a lateral crystallization ELA process to form a polycrystalline region having elongated grain structures with a crystal orientation;
c) forming a first TFT having a first channel oriented at a first angle relative to the crystal orientation in the range of between approximately 30 degrees and 60 degrees; and
d) forming a second TFT having a second channel oriented at a second angle relative to the crystal orientation in the range of between approximately 30 degrees and 60 degrees.

6. The method of claim 5, wherein the first channel is oriented at a first angle relative to the crystal orientation of approximately 45 degrees.

7. The method of claim 5, wherein the second channel is oriented at a second angle relative to the crystal orientation of approximately 45 degrees.

8. The method of claim 5, wherein the first channel is oriented relative to the second channel at an angle of approximately 90 degrees.

9. A method of processing an LCD substrate comprising the steps of:
a) depositing amorphous silicon on a substrate;
b) annealing a region on the substrate using a lateral crystallization ELA process to form a polycrystalline region having a predominant crystal orientation;
c) forming column drivers over the polycrystalline region, the column drivers having column channels oriented at an angle in the range of between 30 and 60 degrees relative to the predominant crystal orientation; and
d) forming row drivers over the polycrystalline region, the row drivers having row channels oriented at an angle in the range of between 30 and 60 degrees relative to the predominant crystal orientation.

10. The method of claim 9, wherein the column channels are oriented at approximately 45 degrees relative to the predominant crystal orientation.

11. The method of claim 9, wherein the row channels are oriented at approximately 45 degrees relative to the predominant crystal orientation.

12. The method of claim 9, wherein the column channels and the row channels are oriented at an angle of approximately 90 degrees relative to each other.

13. A liquid crystal display (LCD) device comprising:
a) a transparent substrate;
b) a layer of semiconductor material having a polycrystalline region with a predominant crystal orientation overlying the transparent substrate;
c) a first set of thin film transistors having channels oriented at an angle in the range between 30 and 60 degrees relative to the predominant crystal orientation of the polycrystalline region; and
d) a second set of thin film transistors having channels oriented at an angle in the range between 30 and 60 degrees relative to the predominant crystal orientation of the polycrystalline region.

14. The LCD device of claim 13, wherein the transparent substrate is quartz, glass or plastic.

15. The LCD device of claim 13, wherein the semiconductor material is silicon.

16. The LCD device of claim 13, wherein the first set of thin film transistors have channels oriented at approximately 45 degrees relative to the predominant crystal orientation.

17. The LCD device of claim 13, wherein the second set of thin film transistors have channels oriented at approximately 45 degrees relative to the predominant crystal orientation.

18. The LCD device of claim 13, wherein the first set of thin film transistors have channels oriented at approximately 90 degrees relative to the second set of thin film transistor channels.
